(19) United States
(12) Patent Application Publication
(10) Pub. No.: US 2013/0146858 A1
(43) Pub. Date: Jun. 13, 2013

(54) SEMICONDUCTORS BASED ON SUBSTITUTED [1]BENZOTHIENO[3,2-b][1]-BENZOTHIOPHENES

(71) Applicants: Timo Meyer-Friedrichsen, Krefeld (DE); Knud Reuter, Krefeld (DE); Andreas Elschner, Mulheim (DE); Marcus Halik, Erlangen (DE)

(72) Inventors: Timo Meyer-Friedrichsen, Krefeld (DE); Knud Reuter, Krefeld (DE); Andreas Elschner, Mulheim (DE); Marcus Halik, Erlangen (DE)

(73) Assignee: Heraeuss Precious Metals Metals GmbH & Co., KG, Hanau (DE)

(21) Appl. No.: 13/809,946

(22) PCT Filed: Jul. 19, 2011
(86) PCT No.: PCT/EP11/03605

§ 371 Date: Feb. 27, 2013

Related U.S. Application Data
(60) Provisional application No. 61/368,326, filed on Jul. 28, 2010.

(30) Foreign Application Priority Data
Jul. 21, 2010 (DE) 102010031897

(51) Int. Cl. H01L 51/00

(52) U.S. Cl. CPC H01L 51/0074; H01L 51/0002
USPC 257/40; 438/99; 549/42

(57) ABSTRACT

The present invention relates to compounds of the general formula (I) wherein Z corresponds a to — a C₁-C₂₂-alkyl radical substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ(R²═C₁-C₁₈-alkyl, n=an integer from 1 to 3), thiol groups or trialkoxysilyl radicals —Si(OR³)₃ (R³═C₁-C₁₈-alkyl), — a C₅-C₁₂-cycloalkyl radical substituted by halogen, phosphonic acid or phosphonic acid ester groups—P(O) (OR¹)₂ (wherein the radicals R¹ can be identical or different and correspond to a hydrogen atom or C₁-C₁₂-alkyl), sulphonic acid groups —SO₃H, halosilyl radicals —SiHal₋ₙR²₃₋ₙ(R²═C₁-C₁₈-alkyl, n=an integer from 1 to 3), thiol groups or trialkoxysilyl radicals —Si(OR³)₃ (R³═C₁-C₁₈-alkyl), — a C₆-C₁₄-aryl radical or heteroaryl radical from the group of the thienyl, pyrryl, furyl or pyridyl radicals substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl), or — a C₇-C₃₀-aralkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl) or a trialkylsilyl radical R⁵R⁶R⁷Si, in which R⁵, R⁶, R⁷ independently of each other are identical or different C₁-C₁₈-alkyl radicals. The present invention also relates to a semiconductor layer, an electronic component, a process for the production of an electronic component, the electronic component obtainable by this process and the use of compounds of the general formula (I).

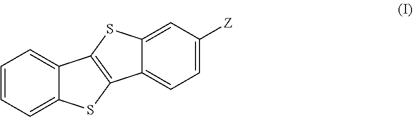

The invention relates to monosubstituted [1]benzothieno[3,2-b][1]-benzothiophenes (BTBT5), a semiconductor layer, an electronic component, a process for the production of an electronic component, the electronic component obtainable by this process and the use of monosubstituted [1]benzothieno[3,2-b][1]-benzothiophenes.

The field of molecular electronics has developed rapidly in the last 15 years with the development of organic conducting and semiconducting compounds. During this time a large number of compounds which have semiconducting or electro-optical properties have been found. It is general understanding that molecular electronics will not displace conventional semiconductor components based on silicon. Instead, it is assumed that molecular electronic components will open up novel fields of use in which suitability for coating large areas, structural flexibility, processability at low temperatures and low costs will be prerequisites. Semiconducting organic compounds are currently being developed for fields of use such as organic field effect transistors (OFETs), organic light-emitting diodes (OLEDs), sensors and photovoltaic elements. By simple structuring and integration of OFETs in integrated organic semiconductor circuits, inexpensive solutions for intelligent cards (smart cards) or price tags, which could not be realized hitherto with the aid of silicon technology because of the price and lack of flexibility of the silicon components, become possible. OFETs could likewise be used as circuit elements in large-area flexible matrix displays. An overview of organic semiconductors, integrated semiconductor circuits and uses thereof is given, for example, in H. Klauk (editor), Organic Electronics, Materials, Manufacturing and Applications, Wiley-VCH 2006.

A field effect transistor is a three-electrode element in which the conductivity of a narrow conduction channel between two electrodes (called “source” and “drain”) is controlled by means of a third electrode (called “gate”) separated from the conduction channel by a thin insulating layer. The most important characteristic properties of a field effect transistor are the mobility of the charge carriers, which decisively determine the switching speed of the transistor, and the ratio between the currents in the switched and unswitched state, the so-called “On/Off ratio”.

In organic field effect transistors, two large classes of compounds have been used hitherto. Compounds of both classes have continuous conjugated units and are classified into conjugated polymers and conjugated oligomers, depending on the molecular weight and structure.

The distinction between oligomers and polymers is often made to express the fact that there is a fundamental difference in the processing of these compounds. Oligomers often can be vaporized and are applied to substrates via vapour deposition processes. Compounds which can no longer be vaporized and are therefore applied via other processes are often called polymers, regardless of their molecular structure. In the case of polymers, compounds which are soluble in a liquid medium, for example in organic solvents, and can then be applied via appropriate application processes are as a rule sought. A very widely used application process is e.g. the “spin coating” process. Application of semiconducting compounds via the ink-jet process is a particularly elegant method. In this process, a solution of the semiconducting compound is applied to the substrate in the form of very fine droplets and dried. This process allows structuring to be carried out during the application. A description of this application process for semiconducting compounds is described, for example, in Nature, volume 401, p. 685.

A greater potential for arriving at inexpensive organic integrated semiconductor circuits by a simple method and manner is generally attributed to the wet chemistry processes.

Compounds of extremely high purity are an important prerequisite for the production of high quality organic semiconductor circuits. Order phenomena play a major role in semiconductors. Impeding a uniform alignment of the compounds and emphasizing of grain boundaries lead to a dramatic drop in the semiconductor properties, so that organic semiconductor circuits which have been built using compounds which are not of extremely high purity are as a rule unusable. Impurities which remain, for example, can inject charges into the semiconducting compound (“doping”) and thus reduce the On/Off ratio, or serve as charge traps and thus drastically reduce the mobility. Impurities can furthermore initiate the reaction of the semiconducting compounds with oxygen, and oxidizing impurities may oxidize the semiconducting compounds and thus shorten possible storage, processing and operating times.

The purity that is usually necessary is so high that as a rule it cannot be achieved by the known methods of polymer chemistry, such as washing, reprecipitation and extraction. On the other hand, as molecularly uniform and often volatile compounds, oligomers can be purified relatively easily by sublimation or chromatography.

Important representatives of oligomeric semiconducting compounds are, for example, oligothiophenes, in particular those with terminal alkyl substituents according to the formula

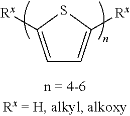

and pentacene

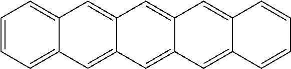 [SMILES: c1ccc2cc3cc4cc5ccccc5cc4cc3cc2c1]

Typical mobilities, e.g. for α,α′-dihexylquater-, -quinque- and -sexithiophene, are 0.05-0.1 cm²/Vs. Pentacene shows higher mobilities, but can be processed only by vapour deposition because of its very low solubility. Substituted pentacenes, e.g. 6,13-bis(triisopropylsilylethynyl)-pentacene, can be processed from solution, but show a lack of stability to environmental influences.

As a rule, the fall in the semiconducting properties during processing of oligomeric compounds from solution is attributed to the moderate solubility and low tendency towards film formation of the oligomeric compounds. Thus, inhomogeneities are attributed, for example, to precipitates during the drying from the solution (Chem. Mater., 1998, volume 10, p. 633).

Semiconductor films processed from solution therefore continue to have poorer properties than those which have been vapour-deposited. There is therefore a need for semiconductors which have improved properties after processing from solvents.

The present invention was based on the object of overcoming the disadvantages resulting from the prior art in connection with semiconducting organic compounds, in particular in connection with the use of such semiconducting organic compounds as a constituent of semiconductor layers in electronic components.

The object of the present invention in particular was to provide organic compounds which can be processed both from the usual solvents and by vapour deposition and which result in semiconducting films with good properties. Such compounds would be outstandingly suitable for application of organic semiconducting layers over large areas.

In addition, in the production of semiconductor layers from these organic compounds, high quality layers of uniform thickness and morphology which are suitable for electronic uses should be formed.

A contribution towards achieving the abovementioned objects is made by compounds of the general formula (I)

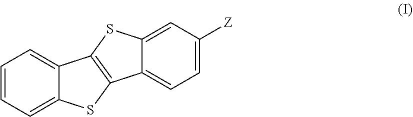

wherein Z corresponds to
a C₁-C₂₂-alkyl radical substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl),
a C₅-C₁₂-cycloalkyl radical substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalR²₃₋ₙ (R²═C₁-C₁₈-alkyl, n=an integer from 1 to 3), thiol groups or trialkoxysilyl radicals Si(OR³)₃ (R³═C₁-C₁₈-alkyl),
a C₆-C₁₄-aryl radical or heteroaryl radical from the group of the thienyl, pyrryl, furyl or pyridyl radicals substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl),
a C₇-C₃₀-aralkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl) or
a trialkylsilyl radical R⁵R⁶R⁷Si, in which R⁵, R⁶, R⁷ independently of each other are identical or different C₁-C₁₈-alkyl radicals.

In this context, F, Cl, Br and I are preferred as halogen.

Compounds which are particularly preferred according to the invention are those in which Z corresponds to a radical -A-R⁴, in which
A represents a preferably unbranched C₁-C₂₂-alkylene radical, particularly preferably a preferably unbranched C₁-C₁₈-alkylene radical and most preferably a preferably unbranched C₁-C₁₂-alkylene radical and
R⁴ represents halogen (Hal), particularly preferably F, Cl, Br or I, a phosphonic acid or phosphonic acid ester group —P(O)(OR¹)₂ (wherein the radicals R¹ can be identical or different and correspond to a hydrogen atom or C₁-C₁₂-alkyl, particularly preferably an ethyl or methyl group), a sulphonic acid group —SO₃H, a halosilyl radical —SiHalₙR²₃₋ₙ (Hal=F, Cl, Br or I, R²═C₁-C₁₈-alkyl, n=an integer from 1 to 3), a thiol group, a trialkoxysilyl radical —Si(OR³)₃ (R³═C₁-C₁₈-alkyl) or a C₆-C₁₄-aryl radical or heteroaryl radical from the group of the thienyl, pyrryl, furyl or pyridyl radicals.

It has been found, surprisingly, that certain monosubstituted [1]benzothieno[3,2-b][1]-benzothiophene derivatives give particularly suitable films with particular properties. This is surprising and unexpected, since to date only disubstituted derivatives have the required solubility for wet processing—in contrast to sparingly soluble unsubstituted derivatives. A disadvantage of the known disubstituted BTBT derivatives of the prior art, however, is e.g. the significantly reduced vapour pressure of the dialkylated BTBTs, which makes processing by vapour deposition difficult.

The electrical properties of films from the monosubstituted BTBTs are also improved. This is completely unexpected since one of the prerequisites for adequate mobilities of OTFT with oligomeric semiconductors is an optimized layer morphology. According to the prior art to date, this is achieved in particular when symmetric compounds render possible an optimum arrangement, see e.g. the symmetrically substituted acene derivatives and their crystal arrangements, as described in U.S. Pat. No. 6,690,029 or in Chem. Rev. 2006, volume 106, p. 5028-5048 and in Angew. Chem. 2008, volume 120, p. 460-492, or also the symmetrically substituted BTBT derivatives, such as are described in H. Ebata, T. Izawa, E. Miyazaki, K. Takimiya, M. Ikeda, H. Kuwabara, T. Yui, J. Am. Chem. Soc. 129, 15732-15733 (2007), and the patent applications WO-A-2006/077888, WO-A-2007/125671 and WO-A-2008/047896.

According to a particularly preferred embodiment of the monosubstituted [1]benzothieno[3,2-b][1]-benzothiophene derivatives according to the invention, Z represents a radical -A-R⁴, in which
A represents a preferably unbranched straight-chain C₁-C₁₈-alkylene radical (—(CH₂)ₙ—, wherein n is an integer from 1 to 18) and
R⁴ represents halogen, preferably F, Cl, Br or I, or a phosphonic acid or phosphonic acid ester group —P(O)(OR¹)₂ (wherein the radicals R¹ can be identical or different and correspond to a hydrogen atom or C₁-C₁₂-alkyl, particularly preferably an ethyl or methyl group).

According to a still more preferred embodiment of the monosubstituted [1]benzothieno[3,2-b][1]-benzothiophene derivatives according to the invention, Z represents a radical -A-R⁴, in which
A represents a preferably unbranched straight-chain C₁-C₁₂-alkylene radical (—(CH₂)ₙ—, wherein n is an integer from 1 to 12) and
R⁴ represents a phosphonic acid group —P(O)(OH)₂.

EP-A-1 531 155 claims the use of mono-functionalized semiconductor molecules as semiconductor layers in electronic components. In particular, these compounds form monomolecular layers. Due to their structure, the compounds can build up a monomolecular layer here which has both the function of the dielectric layer and that of the semiconductor layer. Nature 2008, 455, 956 furthermore describes the use of such mono-functionalized semiconductor molecules as a monomolecular semiconductor layer on a silicon oxide surface as a dielectric. In Nano Letters 2010, vol. 10, p. 1998, monomolecular layers of the same compound are obtained on a polymeric dielectric. In principle, the compounds of the formula (I) according to the invention described above are suitable for the production of monomolecular layers on oxidic or polymeric surfaces.

The synthesis of the compounds of the general formula (I) can be carried out e.g. in two stages by reacting BTBT in at least a 1:1 molar ratio with a carboxylic acid chloride Z′—CO—Cl, wherein Z′ denotes a radical which corresponds to a radical Z shortened by one CH₂ group. The intermediate product of the general formula (II) thereby formed is isolated and then reduced to give a compound of the general formula (I):

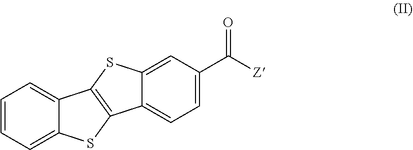

This reduction can be carried out, for example, with hydrazine or with the system sodium boranate/aluminium chloride. The compounds of the general formula (I) carrying phosphonic acid groups can be obtained on the basis of this process, for example, by first employing halogen-substituted carboxylic acid chlorides Z′—CO—Cl (that is to say those compounds in which a hydrogen atom in the radical Z′ is replaced by a halogen) and then, after the reduction of the carbonyl group, replacing the halogen group by a phosphonic acid or phosphonic acid ester group, for example by reaction with phosphonic acid triethyl ester, optionally followed by a reaction with trimethylsilyl bromide for dealkylation.

A contribution towards achieving the abovementioned objects is also made by a semiconductor layer comprising compounds of the general formula (I)

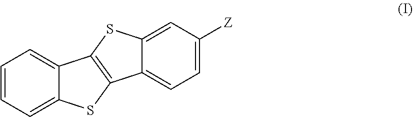

in which Z corresponds to
an optionally branched, but preferably unbranched, C₁-C₂₂-alkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl, particularly preferably an ethyl or methyl group), sulphonic acid groups —SO₃H, halosilyl radicals —SiHalₙR²⁻ⁿ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl),
a C₅-C₁₂-cycloalkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl, particularly preferably an ethyl or methyl group), sulphonic acid groups —SO₃H, halosilyl radicals —SiHalₙR²₃₋ₙ (R²=n=an integer from 1 to 3, Hal=F, Cl, Br or I), thiol groups or trialkoxysilyl radicals —Si(OR³)₃ (R³═C₁-C₁₈-alkyl),
a C₆-C₁₄-aryl radical or heteroaryl radical from the group of the thienyl, pyrryl, furyl or pyridyl radicals, optionally substituted by halogen, preferably by F, Cl, Br or I, phosphonic acid or phosphonic acid ester groups —P(O)(OR¹)₂ (wherein the radicals R^{I} can be identical or different and correspond to a hydrogen atom or C₁-C₁₂-alkyl, particularly preferably an ethyl or methyl group), sulphonic acid groups —SO₃H, halosilyl radicals —SiHalR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl),
a C₇-C₃₀-aralkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl, particularly preferably an ethyl or methyl group), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl) or
a trialkylsilyl radical R⁴R⁵R⁶Si, in which R⁴, R⁵, R⁶ independently of each other are identical or different, straight-chain or branched C₁-C₁₈-alkyl radicals.

Those layers of the compounds of the general formula (I) which have a mobility for charge carriers of at least 10⁻⁴ cm²/Vs are particularly preferred. Charge carriers are e.g. positive hole charges. Charge mobilities can be determined, for example, as described in M. Pope and C. E. Swenberg, Electronic Processes in Organic Crystals and Polymers, 2nd ed., p. 709-713 (Oxford University Press, New York Oxford 1999).

The preparation of the above-described compounds of the general formula (I) can be carried out in the same manner as the preparation of the abovementioned compounds of the general formula (I) according to the invention.

According to a particular embodiment of the semiconductor layer according to the invention, Z corresponds to a radical -A-R⁴, in which
A represents a preferably unbranched C₁-C₂₂-alkylene radical, particularly preferably a preferably unbranched C₁-C₁₈-alkylene radical and most preferably a preferably unbranched C₁-C₁₂-alkylene radical and
R⁴ represents halogen, preferably F, Cl, Br or I, a phosphonic acid or phosphonic acid ester group —P(O)(OR¹)₂ (wherein the radicals R¹ can be identical or different and correspond to a hydrogen atom or C₁-C₁₂-alkyl, particularly preferably an ethyl or methyl group), a sulphonic acid group —SO₃H, a halosilyl radical —SiHalₙR²_{3-n —}(R²═C₁-C₁₈-alkyl, n=an integer from 1 to 3, Hal=F, Cl, Br or I), a thiol group, a trialkoxysilyl radical —Si(OR³)₃ (R³═C₁-C ₁₈-alkyl) or a C₆-C₁₄-aryl radical or heteroaryl radical from the group of the thienyl, pyrryl, furyl or pyridyl radicals, particularly preferably a halogen or a phosphonic acid or phosphonic acid ester group and most preferably a phosphonic acid group.

In this case, it is particularly preferable for the semiconductor layer to comprise a monomolecular layer of the compounds of the general formula (I), very particularly preferably a self-assembled monolayer (SAM layer) of the compounds of the general formula (I).

Compounds which are furthermore preferably to be employed according to the invention are those in which Z represents unsubstituted, unbranched or branched C₁- to C₁₈-alkyl radicals. In this connection, semiconductor layers which are particularly preferred are those which comprise as a constituent compounds of the general formula (I), wherein Z is, for example, n-tridecyl, n-dodecyl, n-hexyl or ethyl, i.e. the following compounds of the formulae (I-1) to (I-4):

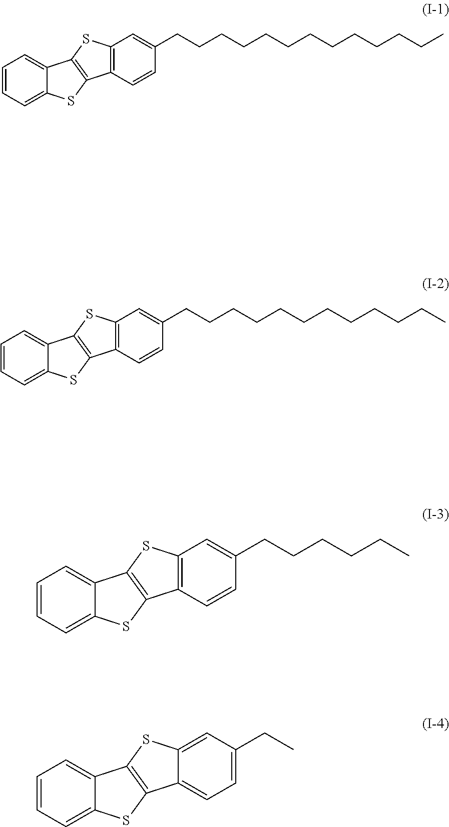

2-Tridecyl-BTBT (I-1) is very particularly preferably to be employed.

A contribution towards achieving the abovementioned objects is also made by an electronic component comprising the above-described semiconductor layer according to the invention, the component preferably being a field effect transistor (FET), a light-emitting component, in particular an organic light-emitting diode, a photovoltaic cell, a laser or a sensor. A field effect transistor, in particular an organic field effect transistor, comprising a substrate as a gate electrode, preferably a silicon wafer with a silicon dioxide layer, an insulator layer applied to the substrate, for example a polystyrene layer or an aluminium oxide layer, a semiconductor layer which is applied to the insulator layer and comprises the compounds of the general formula (I), and electrodes (drain and source) applied to the semiconductor layer, is particularly preferred as the electronic component.

If, in particular, the radical Z in the compound of the general formula (I) corresponds to the radical -A-R⁴ described above, it is preferable for the electronic component to comprise the compound of the general formula (I) as a monomolecular semiconductor layer, particularly preferably as a self-assembled monolayer (SAM). In this connection, it may furthermore be advantageous if in the electronic components, preferably in a field effect transistor, such a monolayer assumes both the function of the semiconductor layer and the function of the dielectric layer (insulator layer).

If, in particular, the radical Z in the compound of the general formula (I) corresponds to a C₁-C₂₂-alkyl radical, a C₅-C₁₂-cycloalkyl radical, a C₆-C₁₄-aryl radical or heteroaryl radical from the group of the thienyl, pyrryl, furyl or pyridyl radicals, a C₇-C₃₀-aralkyl radical or a trialkylsilyl radical R⁵R⁶R⁷Si, in which R⁵, R⁶, R⁷ independently of each other are identical or different, straight-chain or branched C₁-C₁₈-alkyl radicals, it is furthermore preferable for the electronic component to correspond to a field effect transistor.

Suitable substrates for the formation of layers, in particular of monomolecular layers from the compounds of the general formula (I) are oxidic surfaces, such as, for example, indium tin oxide (ITO), zinc oxide, aluminium oxide, silicon oxide, iron oxide, or polymeric surfaces, which are activated, if appropriate, by a pretreatment, for example by a plasma treatment or suitable hydrolysis processes.

Compounds of the general formula (I) which are preferably used for the formation of monomolecular layers on oxidic surfaces are those in which Z corresponds to the radical -A-R⁴ described above and in which R⁴ corresponds to a phosphonic acid or phosphonic acid ester group —P(O)(OR¹)₂ (wherein the radicals R¹ can be identical or different and correspond to a hydrogen atom or C₁-C₁₂-alkyl, particularly preferably an ethyl or methyl group), a halosilyl radical —SiHalₙR²₃₋ₙ (R²═C₁-C₁₈-alkyl, n=an integer from 1 to 3, Hal=F, Cl, Br or I), a thiol group or a trialkoxysilyl radical —Si(OR³)₃ (R³═C₁-C₁₈-alkyl). Compounds of the general formula (I) which are very particularly preferably used for the production of the monomolecular layers are those in which R¹ corresponds to a phosphonic acid group or a halosilyl radical —SiHalₙR³⁻ⁿ (R¹═C₁-C₂-alkyl, n=an integer from 1 to 3, Hal=F, Cl, Br or I).

A contribution towards achieving the abovementioned objects is also made by a process for the production of an electronic component, comprising the process steps:
i) provision of a substrate;
ii) application of a layer comprising compounds of the general formula (I) to the substrate

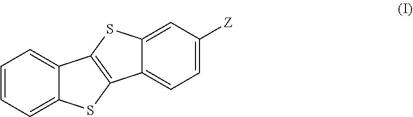

wherein Z corresponds to
a C₁-C₂₂-alkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl),
a C₅-C₁₂-cycloalkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³=alkyl),
a C₆-C₁₄-aryl radical or heteroaryl radical from the group of the thienyl, pyrryl, furyl or pyridyl radicals, optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl), or
a C₇-C₃₀-aralkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl) or
a trialkylsilyl radical R⁵R⁶R⁷Si, in which R⁵, R⁶, R⁷ independently of each other are identical or different C₁-C₁₈-alkyl radicals.

The compounds of the general formula (I) to be used according to the invention or according to the invention are typically readily soluble in the usual organic solvents and are therefore outstandingly suitable for processing from solution. Solvents which are suitable in particular are aromatics, ethers or halogenated aliphatic hydrocarbons, such as, for example, toluene, xylenes, chlorobenzene, o-dichlorobenzene, methyl tert-butyl ether, tetrahydrofuran, methylene chloride or chloroform, or mixtures of these. The compounds of the general formula (I) accordingly have good semiconducting and moreover outstanding film formation properties. The compounds to be used according to the invention are therefore very particularly suitable for coating over a large area. The semiconducting compounds of the general formula (I) to be used according to the invention or according to the invention furthermore have an outstanding heat stability and good ageing properties.

The dissolving process is preferably carried out at room temperature, but can also be carried out at elevated temperatures. Because of the outstanding solubility of the compounds of the general formula (I) to be used according to the invention or according to the invention, however, this is not necessary as a rule. The solutions obtained are stable and processable.

The compounds of the general formula (I) according to the invention or to be used according to the invention are soluble in the abovementioned conventional solvents, such as aromatics, ethers or halogenated aliphatic hydrocarbons, to the extent of at least 0.1 wt. %, preferably at least 1 wt. %, particularly preferably at least 5 wt. %, in each case based on the weight of solvent.

A structured silicon wafer or a coated glass substrate, for example coated with ITO, can serve, for example, as the substrate in the electronic components according to the invention on to which the semiconductor layer comprising the compounds of the general formula (I) is applied in process step ii). The compounds of the general formula (I) according to the invention or to be used according to the invention can be applied to the substrate from solutions by the known processes, for example by spraying, dipping, printing and knife coating, spin coating and by ink-jet printing, particularly preferably by spin coating from a suitable solvent, e.g. toluene, by dripping on or by an ink-jet printing process.

Vapour deposition of the compounds of the general formula (I) according to the invention or to be used according to the invention is likewise possible. In this context, the compounds of the general formula (I) according to the invention or to be used according to the invention are distinguished by a high volatility. It is advantageously higher, for example, than in the case of corresponding disubstituted compounds, such as are described e.g. by Takimiya et al. (see above), whereby processing or processability by vapour deposition is not described at all in the literature reference mentioned.

The layers produced by the process according to the invention comprising the compounds of the general formula (I) can be further modified after the application, for example by a heat treatment, or e.g. by laser ablation for the purpose of structuring.

The compounds of the general formula (I) according to the invention or to be used according to the invention, in particular those in which Z corresponds to the radical -A-R⁴ described above, form high quality layers of uniform thickness and morphology from evaporated solutions and are therefore suitable for electronic uses.

According to a particular embodiment of the process according to the invention, Z corresponds to the radical -A-R⁴ described above and the compounds of the general formula (I) are applied to the component as a monomolecular layer in process step ii). This application as a monomolecular layer preferably takes place in this context by a self-organisation of the compounds of the general formula (I) (SAM layer).

A contribution towards achieving the abovementioned objects is also made by the use of compounds of the general formula (I)

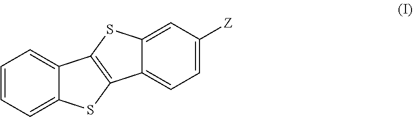

wherein Z corresponds to
a C₁-C₂₂-alkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl),
a C₅-C₁₂-cycloalkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals Si(OR³)₃ (R³═C₁-C₁₈-alkyl),
a C₆-C₁₄-aryl radical or heteroaryl radical from the group of the thienyl, pyrryl, furyl or pyridyl radicals, optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl), or
a C₇-C₃₀-aralkyl radical optionally substituted by halogen, preferably by F, Cl, Br or I, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3, Hal=F, Cl, Br or I), thiol groups or trialkoxysilyl radicals —Si(OR³)₃ (R³═C₁-C₁₈-alkyl) or
a trialkylsilyl radical R⁵R⁶R⁷Si, in which R⁵, R⁶, R⁷ independently of each other are identical or different C₁-C₁₈-alkyl radicals,
   in a semiconducting layer in electronic components, preferred electronic components being those which have already been mentioned above as preferred electronic components in connection with the electronic components according to the invention.

According to a particular embodiment of the use according to the invention, Z corresponds to the radical -A-R⁴ defined above and the semiconductor layer is a monomolecular layer, particularly preferably an SAM layer, which comprises the compounds of the general formula (I).

The following examples and figures serve to illustrate the invention by way of example and are not to be interpreted as a limitation.

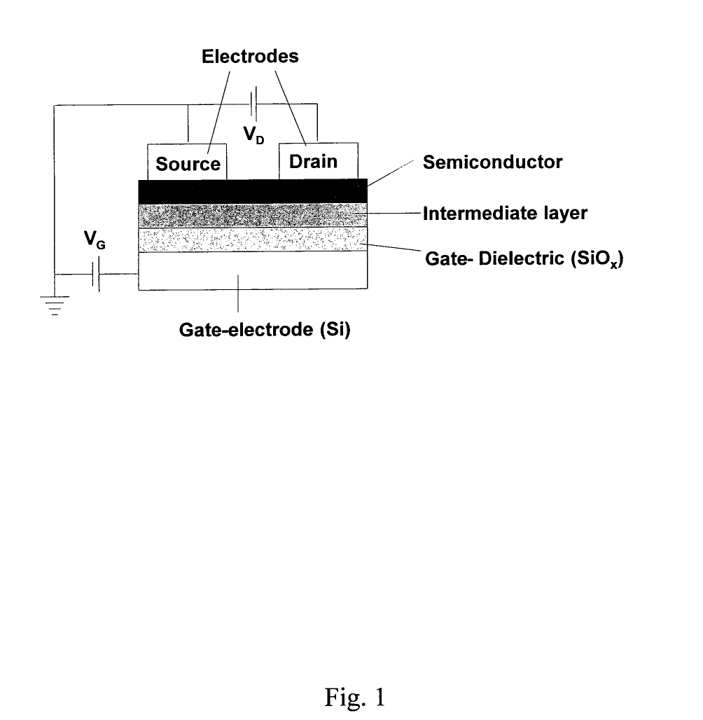

FIG. 1 shows a field effect transistor according to the invention, in which a semiconductor layer according to the invention has been applied to a dielectric intermediate layer as the substrate.

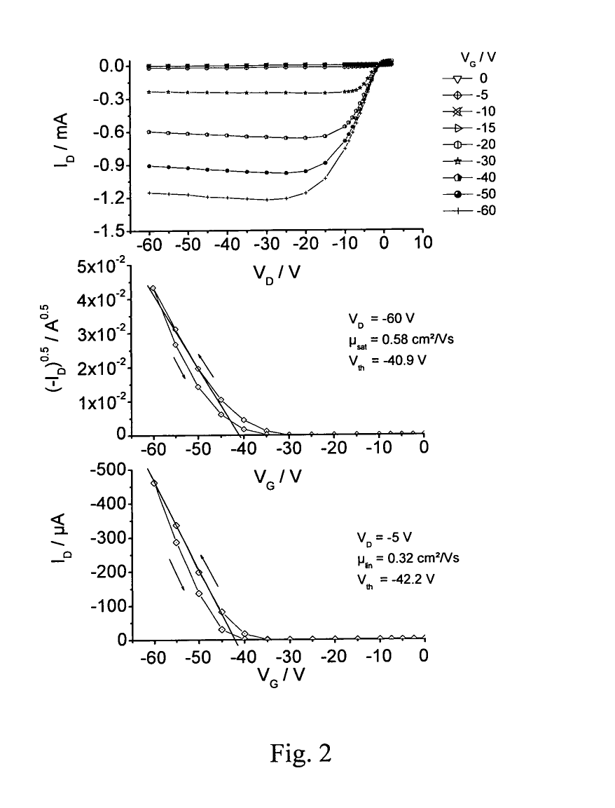

FIG. 2 shows the characteristic data of the field effect transistor produced in Example 6h.

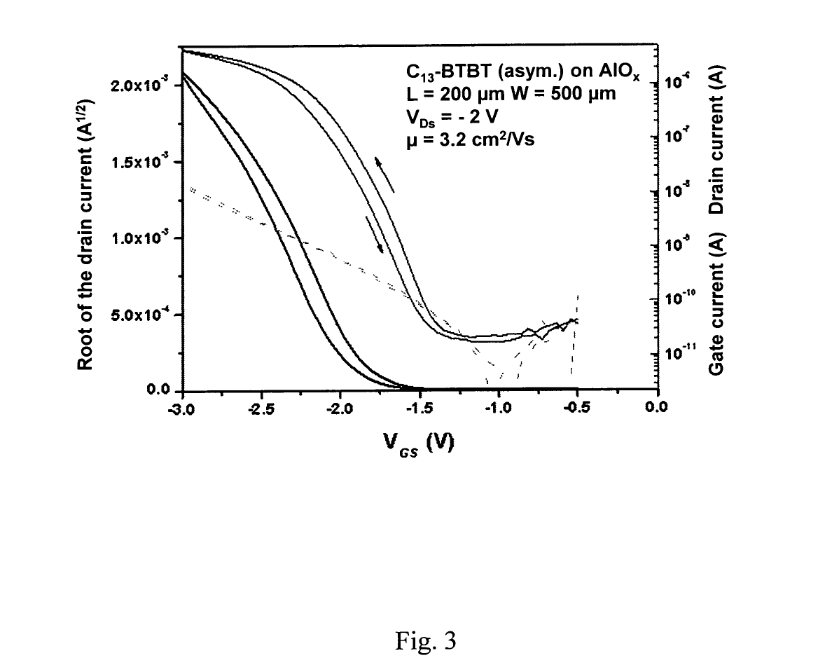

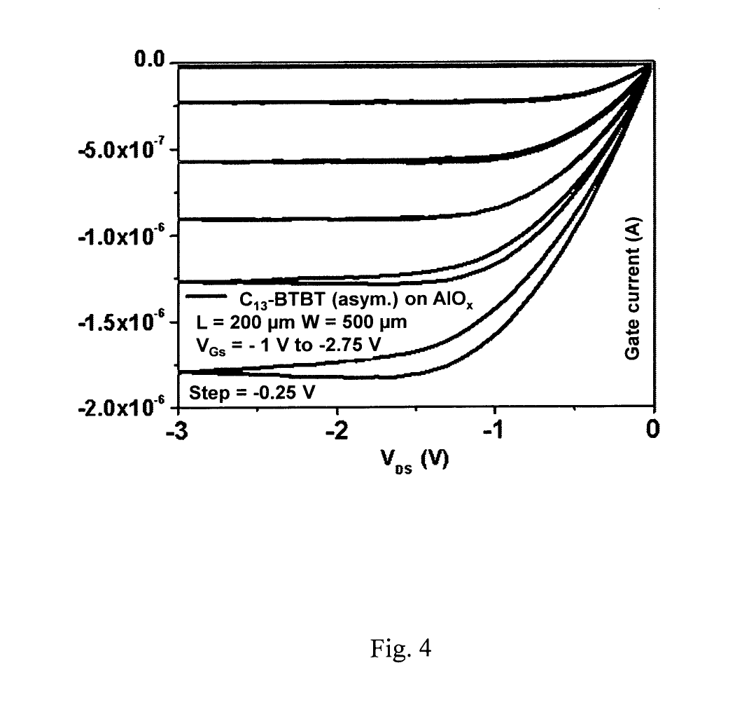

FIGS. 3 and 4 show the results of measurements on the transistor produced in Example 8.

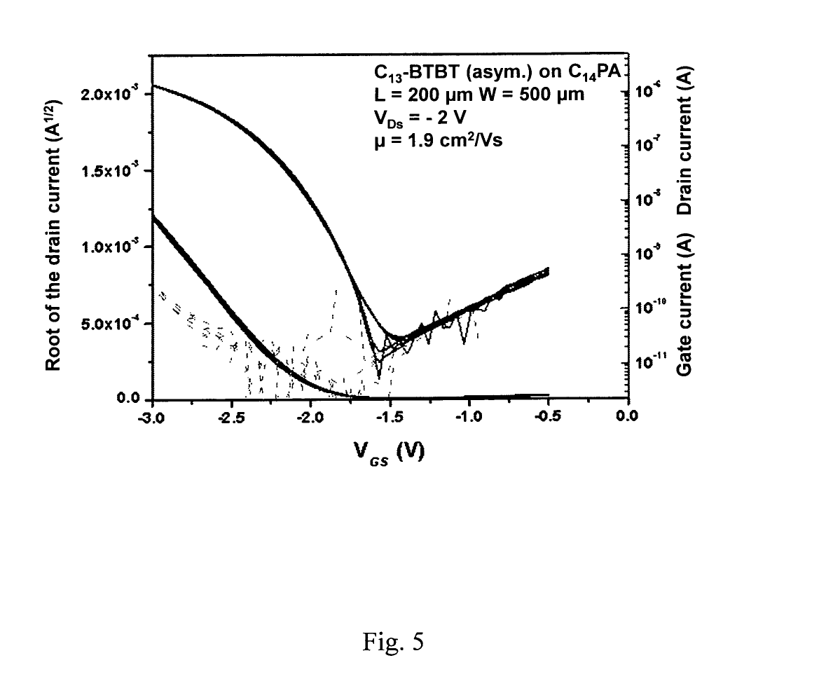

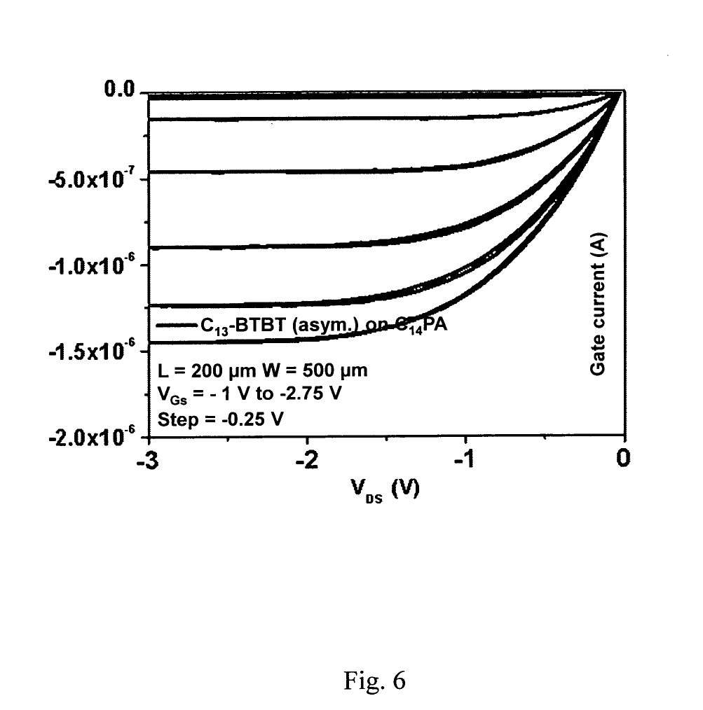

FIGS. 5 and 6 show the results of measurements on the transistor produced in Example 9.

### EXAMPLES

### Preparation Example 1

### 2-Tridecyl-[1]benzothieno[3,2-b][1]benzothiophene (2-tridecyl-BTBT; (I-1))

### a) [1]Benzothieno[3,2-b][1]benzothien-2-yl)tridecan-1-one (2-tridecanoyl-BTBT)

2.0 g (8.3 mmol) of BTBT were initially introduced into 150 ml of dry methylene chloride. 4.0 g (30 mmol) of aluminium chloride were metered into this mixture at −20° C. and the mixture was then cooled to −70° C. Thereafter, 7.71 g (33.1 mmol) of n-tridecanoyl chloride were added dropwise in the course of 20 minutes. The mixture was subsequently stirred at −70° C. for 1.5 h. The reaction was then stopped by dropwise addition of 75 ml of water, the reaction mixture being gradually warmed to 23° C. The solid which had precipitated out was filtered off and recrystallized from toluene/ethanol 1:1. Yield 2.2 g=61% of th. ¹H-NMR [CDCl₃; ppm (δ) against TMS; 400 MHz)]: 8.56 (d, J=1.2 Hz, 1H); 8.06 (dd, J¹=1.2 Hz, J²=8.4 Hz, 1H); 7.94 (m, 3H); 7.48 (m, 2H); 3.07 (t, J=7.4 Hz, 2 H); 1.80 (quint, J=7.4 Hz, 2H); 1.47-1.22 (m, 18 H); 0.88 (t, J=7.0 Hz, 3H).

### b) 2-Tridecyl-BTBT

1.81 g (47.8 mmol) of sodium borohydride were added to a solution of 2.10 g (4.8 mmol) of 2-tridecanoyl-BTBT (from Preparation Example 1a) in 30 ml of dry tetrahydrofuran at 23° C. Thereafter, 3.50 g (26.3 mmol) of aluminium chloride were added. After the exothermic reaction had subsided, the mixture was stirred under reflux for 2 h. Thereafter, 50 ml of water were added dropwise at 21° C. After the exothermic reaction, which proceeds with foaming, had subsided, 2.0 g (98% of th.) of the product were filtered off with suction and can be purified by column chromatography over silica gel with toluene as the mobile phase or by sublimation. ¹H-NMR [CDCl₃; ppm (δ) against TMS; 400 MHz)]: 7.91 (d, J=8.0 Hz, 1H); 7.86 (dd, J¹=1.2 Hz, J²=7.8 Hz, 1H); 7.79 (d, J=8.0 Hz, 1H); 7.72 (d, J=1.2 Hz, 1H); 7.45 (ddd, J¹=1.2 Hz, J²=7.6 Hz, J³=8.0 Hz, 1H); 7.38 (ddd, J¹=1.5 Hz, J²=7.0 Hz, J³=7.8 Hz, 1H); 7.28 (dd, J¹=1.5 Hz, J²=8.3 Hz, 1H); 2.76 (t, J=7.8 Hz, 2H); 1.70 (quint, J=7.5 Hz, 2H); 1.34 (m, 2H); 1.25 (m, 18H); 0.87 (t, J=6.9 Hz, 3H).

### Preparation Example 2

2-Dodecyl-[1]benzothieno[3,2-b][1]benzothiophene (2-dodecyl-BTBT; (I-2))

### a) [1]Benzothieno[3,2-b][1]benzothien-2-yl)dodecan-1-one (2-dodecanoyl-BTBT)

2.0 g (8.3 mmol) of BTBT were initially introduced into 150 ml of dry methylene chloride. 4.0 g (30 mmol) of aluminium chloride were metered into this mixture at −30° C. and the mixture was then cooled to −70° C. Thereafter, 7.28 g (33.3 mmol) of n-dodecanoyl chloride were added dropwise in the course of 10 minutes. The mixture was subsequently stirred at −70° C. for 1 h. After stirring at 23° C. for a further 5 h, the reaction was stopped by dropwise addition of 40 ml of water, the reaction mixture warming to 23° C. The solid which had precipitated out was filtered off and recrystallized from toluene. The mixture was then chromatographed over silica gel with toluene as the mobile phase. Yield 0.4 g. ¹H-NMR [CDCl₃; ppm (8) against TMS; 400 MHz)]: 8.55 (dd, J¹=0.6 Hz, J²=1.5 Hz, 1H); 8.05 (dd, J¹=1.5 Hz, J²=8.4 Hz, 1H); 7.93 (m, 3H); 7.47 (m, 2H); 3.06 (t, J=7.4 Hz, 2H); 1.79 (quint, J=7.6 Hz, 2H); 1.45-1.23 (m, 16H); 0.88 (t, J=6.6 Hz, 3H).

### b) 2-Dodecyl-BTBT

176 mg (4.7 mmol) of sodium borohydride were added to a solution of 0.4 g (0.9 mmol) of 2-dodecanoyl-BTBT (from Preparation Example 2a) in 5 ml of dry tetrahydrofuran at 23° C. Thereafter, 348 mg (2.6 mmol) of aluminium chloride were added. The mixture was stirred under reflux for 3 h. Thereafter, 15 ml of water were added dropwise, while cooling. After the exothermic reaction had subsided, the product was filtered off with suction, washed with water and then purified by column chromatography over silica gel with toluene as the mobile phase or by sublimation. Yield 230 mg=61% of th. ¹H-NMR [CDCl₃; ppm (δ) against TMS; 400 MHz)]: 7.91 (d, J=8.0 Hz, 1H); 7.86 (d, J=7.8 Hz, 1H); 7.79 (d, J=8.2 Hz, 1H); 7.72 (s, 1H); 7.45 (ddd, J¹=1.0 Hz, J²=7.4 Hz, J³=7.8 Hz, 1H); 7.38 (ddd, J¹=1.0 Hz, J²=6.9 Hz, J³=7.8 Hz, 1H); 7.28 (dd, J¹=1.5 Hz, J²=8.3 Hz, 1H); 2.76 (t, J=7.8 Hz, 2H); 1.70 (quint, J=7.5 Hz, 2H); 1,34 (m, 2H); 1.26 (m, 16H); 0.87 (t, J=6.8 Hz, 3H).

### Preparation Example 3:

### 2-Hexyl-[1]benzothieno[3,2-b][1]benzothiophene (I-3; 2-hexyl-BTBT)

### [1]Benzothieno[3,2-b][1]benzothien-2-yl)hexan-1-one (2-hexanoyl-BTBT)

2.0 g (8.3 mmol) of BTBT were initially introduced into 150 ml of dry methylene chloride. 4.0 g (30 mmol) of aluminium chloride were metered into this mixture at −40° C. and the mixture was then cooled to −70° C. Thereafter, 4.44 g (33 mmol) of n-hexanoyl chloride were added dropwise in the course of 15 minutes. The mixture was subsequently stirred at −70° C. for 7 h. The reaction was then stopped by dropwise addition of 75 ml of water, the reaction mixture being gradually warmed to 23° C. The solid which had precipitated out was filtered (1.53 g of product). The aqueous phase was extracted with methylene chloride. A further 0.85 g of product was isolated from this phase after washing with water and evaporation. Purification was carried out by recrystallization from toluene. Yield 2.38 g =85% of th. ¹H-NMR [CDCl₃; ppm (δ) against TMS; 400 MHz)]: 8.54 (d, J=1.5 Hz, 1H); 8.05 (dd, J¹=1.5 Hz, J²=8.3 Hz, 1H); 7.93 (m, 3H); 7.47 (m, 2H); 3.06 (t, J=7.4 Hz, 2 H); 1.80 (m, 2H); 1.41 (m, 4H); 0.93 (t, J=7.1 Hz, 3H).

### b) 2-Hexyl-BTBT

0.91 g (24.1 mmol) of sodium borohydride were added to a solution of 0.82 g (2.4 mmol) of 2-hexanoyl-BTBT (from Preparation Example 3a) in 13 ml of dry tetrahydrofuran at 23° C. Thereafter, 1.77 g (13.3 mmol) of aluminium chloride were added. The mixture was stirred under reflux for 2 h. Thereafter, 10 ml of water were added dropwise, while cooling. After the exothermic reaction had subsided, 20 ml of ethyl acetate were added, a further 10 ml of water were added and the phases were separated. The aqueous phase was extracted once more with ethyl acetate. The organic phase was washed three times with water. The ethyl acetate phases were then combined and evaporated. Crude yield 0.78 g=99% of th. M.p. 119° C. Purification was carried out by recrystallization from ethyl acetate. ¹H-NMR [CDCl₃; ppm (δ) against TMS; 400 MHz)]: 7.91 (d, J=7.9 Hz, 1H); 7.86 (d, J=7.6 Hz, 1H); 7.78 (d, J=8.0 Hz, 1H); 7.71 (s, 1H); 7.44 (ddd, J¹=1.3 Hz, J²=6.9 Hz, J³=7.8 Hz, 1H); 7.38 (ddd, J¹=1.5 Hz, J²=7.3 Hz, J³=8.3 Hz, 1H); 7.28 (dd, J¹=1.5 Hz, J²=8.3 Hz, 1H); 2.76 (t, J=7.6 Hz, 2H); 1.69 (quint, J=7.6 Hz, 2H); 1.33 (m, 6H); 0.89 (t, J=7.0 Hz, 3H).

### Preparation Example 4

### 2-Ethyl-[1]benzothieno[3,2-b][1]benzothiophene (I-4; 2-ethyl-BTBT)

### a) [1]Benzothieno[3,2-b][1]benzothien-2-yl)ethan-1-one (2-acetyl-BTBT)

4.0 g (16.6 mmol) of BTBT were initially introduced into 300 ml of dry methylene chloride. 6.0 g (45 mmol) of aluminium chloride were metered into this mixture at −30° C. and the mixture was then cooled to −70° C. Thereafter, 3.3 g (42 mmol) of acetyl chloride were added dropwise in the course of 20 minutes. The mixture was subsequently stirred at −70° C. for 5 h. The reaction was then stopped by dropwise addition of 25 ml of water, the reaction mixture being gradually warmed to 23° C. The solid which had precipitated out was filtered off. Further fractions of the product were isolated from the methylene chloride phase and the product was washed with a little cold methylene chloride and water/ethanol. Yield 3.66 g=78% of th. ¹H-NMR [CDCl₃; ppm (δ) against TMS; 400 MHz)]: 8.51 (d, J=1.4 Hz, 1H); 8.03 (dd, J¹=1.5 Hz, J²=8.3 Hz, 1H); 7.91 (m, 2H); 7.89 (d, J=8.3 Hz, 1H); 7.46 (m, 2H); 2.69 (s, 3 H).

### b) 2-Ethyl-BTBT

2.42 g (64 mmol) of sodium borohydride were added to a solution of 1.82 g (6.4 mmol) of 2-acetyl-BTBT (from Preparation Example 4a) in 36 ml of dry tetrahydrofuran at 23° C. Thereafter, 4.69 g (35.2 mmol) of aluminium chloride were added at 0° C. After the exothermic reaction had subsided, the mixture was stirred under reflux for a further 2.5 h. Thereafter, 30 ml of water were added dropwise, while cooling. Thereafter, 20 ml of ethyl acetate were added, a further 10 ml of water were added and the phases were separated. The organic phase was washed twice with water. A total of −0.9 g of very pure 2-ethyl-BTBT thereby precipitated out, m.p. 138-139° C. A further 0.34 g of slightly less pure product was isolated from the mother liquor. Total yield 72% of th. Purification was carried out by recrystallization from ethyl acetate. ¹H-NMR [CDCl₃; ppm (δ) against TMS; 400 MHz)]: 7.91 (d, J=8.0 Hz, 1H); 7.86 (dd, J¹=1.2 Hz, J²=8.0 Hz, 1H); 7.79 (d, J=8.0 Hz, 1H); 7.74 (s, 1H); 7.45 (ddd, J¹=1.4 Hz, J²=7.4 Hz, J³=7.8 Hz, 1H); 7.38 (ddd, J¹=1.1 Hz, J²=6.9 Hz, J³=8.3 Hz, 1H); 7.30 (dd, J¹=1.5 Hz, J²=7.8 Hz, 1H); 2.81 (q, J=7.6 Hz, 2H); 1.33 (t, J=7.6 Hz, 3H).

### Example 1

### 2-(12-Bromo)dodecyl-BTBT

### a) [1]Benzothieno[3,2-b][1]benzothien-2-yl)-12-bromododecan-1-one (2-(12-bromo)dodecanoyl-BTBT)

1.0 g (4.2 mmol) of BTBT were initially introduced into 100 ml of dry methylene chloride. 0.83 g (6.2 mmol) of aluminium chloride were metered into this mixture at −10° C. and the mixture was then cooled to −70° C.

Thereafter, 1.85 g (6.2 mmol) of 12-bromododecanoyl chloride were added dropwise in the course of 20 minutes. The mixture was subsequently stirred at −70° C. for 1.5 h. The reaction was then stopped by dropwise addition of 40 ml of water, the reaction mixture being gradually warmed to 23° C. The aqueous phase was extracted twice with 30 ml of methylene chloride each time, and thereafter the combined organic phases were washed with 50 ml of water. After the solvent had been evaporated off, the solid obtained was washed with a large amount of ethanol and fed to the reduction b) without further purification. M.p. 123° C., yield 1.91 g=91% of th. ¹H-NMR [CDCl₃; ppm (δ) against TMS; 400 MHz)]: 8.54 (d, J=1.0 Hz, 1H); 8.05 (dd, J¹=1.4 Hz, J²=8.3 Hz, 1H); 7.93 (m, 3H); 7.47 (m, 2H); 3.40 (t, J=7.0 Hz, 2 H); 3.06 (t, J=7.3 Hz, 2H); 1.85 (quint, J=6.8 Hz, 2H); 1.79 (quint, J=7.4 Hz, 2H); 1.46-1.25 (m, 14H).

### b) [1]Benzothieno[3,2-b][1]benzothien-2-yl)-12-bromododecane (2-(12-bromo)dodecyl-BTBT)

2.58 g (68.2 mmol) of sodium borohydride were added to a solution of 1.7 g (3.4 mmol) of 2-(12-bromo)dodecanoyl-BTBT (from Example 1a) in 15 ml of dry tetrahydrofuran at 23° C. Thereafter, 0.99 g (7.4 mmol) of aluminium chloride were added at 10° C. After the exothermic reaction had subsided, the mixture was stirred under reflux for 3 h. Thereafter, 10 ml of water were added dropwise at 21° C. After the exothermic reaction, which proceeds with foaming, had subsided, a further 10 ml of water and 20 ml of ethyl acetate were added. The mixture was stirred at 23° C. for 14 h. The product which had precipitated out was filtered off and purified by column chromatography over silica gel with toluene as the mobile phase or by sublimation. Yield 0.7 g (42% of th.); m.p. 87° C. ¹H-NMR [CDCl₃; ppm (δ) against TMS; 400 MHz)]: 7.90 (d, J=7.8 Hz, 1H); 7.86 (d, J=7.7 Hz, 1H); 7.78 (d, J=8.2 Hz, 1H); 7.71 (s, 1H); 7.44 (ddd, J¹=1.2 Hz, J²=6.9 Hz, J³=7.8 Hz, 1H); 7.38 (ddd, J¹=1.2 Hz, J²=7.2 Hz, J³=7.8 Hz, 1H); 7.27 (dd, J¹=1.5 Hz, J²=7.8 Hz, 1H); 3.39 (t, J=6.8 Hz, 2H); 2.75 (t, J=7.7 Hz, 2H); 1.84 (quint, J=6.9 Hz, 2H); 1.69 (quint, J=7.2 Hz, 2H); 1.45-1.23 (m, 16H).

### Example 2

### 2-(11-Bromo)undecyl-BTBT

### a) [1]Benzothieno[3,2-b][1]benzothien-2-yl)-11-bromoundecan-1-one (2-(11-bromo)undecanoyl-BTBT)

1.7 g (7.1 mmol) of BTBT were initially introduced into 125 ml of dry methylene chloride. 1.41 g (10.6 mmol) of aluminium chloride were metered into this mixture at −10° C. and the mixture was then cooled to −70° C. Thereafter, 3.0 g (10.6 mmol) of 11-bromoundecanoyl chloride were added dropwise in the course of 5 minutes. The mixture was subsequently stirred at −70° C. for 1 h. After removal of the cooling and leaving to stand overnight, 30 ml of water were added dropwise to stop the reaction. The organic phase was washed neutral with saturated sodium chloride solution. After the solvent had been evaporated off, the solid obtained was recrystallized with ethanol. Yield 3.32 g=95% of th. ¹H-NMR [CDCl₃; ppm (δ) against TMS; 400 MHz)]: 8.55 (d, J=1.4 Hz, 1H); 8.05 (dd, J¹=1.4 Hz, J²=8.3 Hz, 1H); 7.93 (m, 3H); 7.47 (m, 2H); 3.40 (t, J=6.8 Hz, 2H); 3.06 (t, J=7.3 Hz, 2H); 1.85 (quint, J=7.0 Hz, 2H); 1.80 (quint, J=7.4 Hz, 2H); 1.47-1.628 (m, 12H).

### b) [1]Benzothieno[3,2-b][1]benzothien-2-yl)-11-bromoundecane (2-(11-bromo)undecyl-BTBT)

0.52 g (13.6 mmol) of sodium borohydride was added to 1.65 g (3.4 mmol) of 2-(11-bromo)undecanoyl-BTBT (from Example 2a) in 12 ml of dry tetrahydrofuran at 23° C. Thereafter, 0.99 g (7.4 mmol) of aluminium chloride was added. After the exothermic reaction had subsided, the mixture was stirred at 23° C. for 2 h. Thereafter, 15 ml of water were added dropwise. After the exothermic reaction, which proceeds with foaming, had subsided, 15 ml of ethyl acetate were added. The crude product which had precipitated out was recrystallized together with the fraction obtained from the mother liquor of the organic phase. Yield 0.69 g (43% of th.); m.p. 78° C. ¹H-NMR [CDCl₃; ppm (δ) against TMS; 400 MHz)]: 7.90 (d, J=7.8 Hz, 1H); 7.86 (d, J=7.8 Hz, 1H); 7.78 (d, J=8.1 Hz, 1H); 7.71 (d, J=1.0 Hz, 1H); 7.44 (ddd, J¹=1.0 Hz, J²=7.3 Hz, J³=7.9 Hz, 1H); 7.37 (ddd, J¹=1.3 Hz, J²=7.4 Hz, J³=7.8 Hz, 1H); 7.28 (dd, J¹=1.5 Hz, J²=8.3 Hz, 1H); 3.39 (t, J=6.9 Hz, 2H); 2.76 (t, J=7.6 Hz, 2H); 1.84 (quint, J=7.2 Hz, 2H); 1.70 (quint, J=7.5 Hz, 2H); 1.45-1.24 (m, 14H).

### Example 3

### Diethyl [12-([1]benzothieno[3,2-b]benzothien-2-yl)-dodecyl]phosphonate

[1]Benzothieno[3,2-b][1]benzothien-2-yl)-12-bromodo decane (0.585 g, 1.2-mmol) and phosphoric acid triethyl ester (10 ml) were heated at 160° C. for 16 hours. The volatile constituents were then stripped off in vacuo. The residue was dissolved in toluene and the solution was chromatographed over silica gel. Elution was first carried out with toluene, and the product was then eluted with a mixture of toluene : ethanol 4:1. Yield: 0.44 g (67% of th.) of a pale yellow solid. ¹H-NMR [CDCl₃; ppm (δ) against TMS; 400 MHz)]: 7.90 (d, J=7.89 Hz, 1H); 7.86 (dd, J¹=1.18 Hz, J²=7.69 Hz, 1H); 7.78 (d, J=8.05 Hz, 1H); 7.71 (d, J=0.85 Hz, 1H); 7.44 (m, 1H); 7.38 (m, 1H); 4.09 (m, 4H); 2.75 (t, J=7.57 Hz, 2H); 1.71 (m, 4H); 1.58 (m, 2H); 1.31 (m, Hz).

### Example 4

### [12-([1]Benzothieno[3,2-b]benzothien-2-yl)-dodecyl]phosphonic acid

Diethyl [12-([1]benzothieno[3,2-b]benzothien-2-yl)-dodecyl]pho sphonate (0.218 g, 0.4 mmol) was dissolved in 20 ml of toluene. Trimethylsilyl bromide (1.06 ml, 0.8 mmol) was added dropwise to this solution with a syringe in the course of five minutes and the solution was stirred first at 23° C. for one hour, then at 60° C. for one hour and at 80° C. for 16 hours. After cooling, 10 ml of methanol were added and the mixture was boiled up briefly. The white precipitate was filtered off with suction and recrystallized from THF. Yield: 50 mg (25.5% of th.) of a white solid. MS (ED: m/z (%)=488 (100) [M], 408 (5) [M−P(O)(OH)₂].

### Example 5

### 2-Benzyl-[1]benzothieno[3,2-b][1]benzothiophene

### a) 2-Benzoyl-[1]benzothieno[3,2-b][1]benzothiophene

2.0 g (8.3 mmol) of BTBT were initially introduced into 150 ml of dry methylene chloride. 3.0 g (22.5 mmol) of aluminium chloride were metered into this mixture at −20° C. and the mixture was then cooled to −70° C. Thereafter, 2.95 g (21 mmol) of benzoyl chloride were added dropwise in the course of 5 minutes. The mixture was subsequently stirred at −70° C. for 5 h. The reaction was then stopped by dropwise addition of 25 ml of water, the reaction mixture being gradually warmed to 23° C. The solid which had precipitated out (1.7 g) was filtered off and washed with ethanol/water (m.p. 222° C.). A further 0.4 g of product of practically the same melting point was isolated from the organic phase. The two fractions were fed to the reduction according to Example 1b) without further purification. Yield 2.1 g=73% of th. ¹H-NMR [CDCl₃; ppm (δ) against TMS; 400 MHz)]: 8.40 (m, 1H); 7.95 (m, 4H); 7.85 (m, 2H); 7.63 (tt, J¹=2.0 Hz, J²=7.4 Hz, 1H); 7.56 -7.44 (m, 4H).

### b) 2-Benzyl-[1]benzothieno[3,2-b][1]benzothiophene

2.29 g (60.5 mmol) of sodium borohydride were added to a solution of 2.10 g (6.1 mmol) of 2-benzoyl-[1]benzothieno[3,2-b][1]benzothiophene (from Example 5a) in 30 ml of dry tetrahydrofuran at 22° C. Thereafter, the mixture was cooled to 0° C. and 4.45 g (33.4 mmol) of aluminium chloride were added. After the exothermic reaction had subsided, the mixture was stirred under reflux for 2 h. Thereafter, 30 ml of water were added dropwise at 22° C. After the exothermic reaction, which proceeds with foaming, had subsided, 1.87 g (93% of th.) of practically colourless crystals of the product were filtered off with suction and were washed with water/ethanol and can be purified by column chromatography over silica gel with toluene as the mobile phase or by sublimation. ¹H-NMR [CDCl₃; ppm (δ) against TMS; 400 MHz)]: 7.90 (d, J=7.8 Hz, 1H); 7.86 (dd, J¹=1.5 Hz, J²=7.8 Hz, 1H); 7.79 (d, J=8.2 Hz, 1H); 7.71 (d, J=1.0 Hz, 1H); 7.45 (ddd, J¹=1.5 Hz, J²=7.3 Hz, J³=7.8 Hz, 1H); 7.40 (ddd, J¹=1.5 Hz, J²=7.3 Hz, J³=7.8 Hz, 1H); 7.31 (m, 3H); 7.24 (m, 2H); 4.14 (s, 2H).

### Example 6

### Preparation of the OFET Devices

### a) Substrate for OFET and Cleaning

p-doped silicon wafers polished on one side and with a thermally grown oxide layer 300 nm thick (Sil-Chem) were cut into substrates 25 mm×25 mm in size. The substrates were first cleaned thoroughly. The adhering silicon splinters were removed by rubbing with a clean room wipe (Bemcot M-3, Asahi Kasei Corp.) under running distilled water and the substrates were then cleaned in an aqueous 2% strength water/Mucasol solution at 60° C. for 15 min in an ultrasound bath. Thereafter, the substrates were rinsed with distilled water and spin-dried in a centrifuge. Immediately before coating, the polished surface was cleaned for 10 min in a UV/ozone reactor (PR-100, UVP Inc., Cambridge, UK).

### b) Dielectric Layer

i. Octyldimethylchlorosilane (ODMS): The octyldimethylchlorosilane (Aldrich, 246859) used for the dielectric intermediate layer was poured into a Petri dish so that the base is just covered. The magazine containing the cleaned Si substrates standing on edge was placed on top. Everything was covered with an upturned glass beaker and the Petri dish was heated to 70° C. The substrates remained in the octyldimethylchlorosilane-enriched atmosphere for 15 min.
ii. Hexamethyldisilazane (HMDS): The hexamethyldisilazane (Aldrich, 37921-2) used for the dielectric intermediate layer was poured into a glass beaker containing the magazine with the vertically standing cleaned Si substrates. The silazane covered the substrates completely. The glass beaker was covered and heated to 70° C. on a hot-plate. The substrates remained in the silazane for 24 h. The substrates were then dried in a dry stream of nitrogen.
iii. Polymers: The polymers employed were polystyrene (Aldrich, CAS no. 9003-53-6), Paraloid B-72 (acrylate ester polymer from Dr. G. Kremer, article no. 67400) and COC 5013 (cycloolefin polymer from Topas Advanced Polymers GmbH, article Topas 5013S-04, batch no. 119412). The appropriate polymer was dissolved in toluene in a concentration of 5 mg/ml. Approx. 1 ml of the polymer solution was distributed over the substrate. The thin layer was then produced by means of a spin coater (Karl Suss, RC8). The conditions during the spin coating were: speed of rotation: 2,000 rpm, acceleration: 200 rp(minsec), lid open. After spin coating with the solution, the substrates were laid on a hot-plate and dried at approx. 130° C. for one minute.

### c) Organic Semiconductor

For application of the semiconductor layer from solution, solutions of the compounds from Preparation Examples 1 to 4 in a suitable solvent were prepared. The concentration of the solutions was 0.3 wt. %.

The substrate provided with the dielectric intermediate layer was laid with the polished side up in the holder of a spin coater (Carl Suss, RC8 with Gyrset®) and heated to approx. 70° C. with a hair dryer. Approx. 1 ml of the still hot solution was dripped on to the surface and the solution with the organic semiconductor spin-coated on the substrate at 1,200 rpm for 30 s with an acceleration of 500 rps² and an open Gyrset®. The film produced in this way was dried on a hot-plate at 70° C. for 3 min. The layer was homogeneous and showed no clouding.

For application of the organic semiconductor layer from the gas phase by means of thermal sublimation, the substrate provided with the dielectric layer was transferred to a vapour deposition unit (Univex 350, Leybold). Approx. 25 mg of the compound according to the invention was contained in a thermal evaporator (Mo Boat, Umicore 0482054). Under a pressure of 10⁻³ Pa, the current flowing through the evaporator was increased until the compound according to the invention melted and vaporized.

### d) Application of the Electrodes

The electrodes for the source and drain were then vapour-deposited on this layer. A shadow mask which comprised a galvanically produced Ni foil with 4 recesses of two interlocking combs was used for this. The teeth of the individual combs were 100 μm wide and 4.7 mm long. The mask was laid on the surface of the coated substrate and fixed with a magnet from the reverse.

The substrates were subjected to vapour deposition with gold in a vapour deposition unit (Univex 350, Leybold). The electrode structure produced in this way had a length of 14.85 cm at a separation of 100 μm.

### e) Measurement of the Capacitance

The electrical capacitance of the arrangements was determined by subjecting a substrate, prepared in an identical manner but without the organic semiconductor layer, to vapour deposition in parallel behind the same shadow masks. The capacitance between the p-doped silicon wafer and the vapour-deposited electrodes was determined with a multimeter, MetraHit 18S, Gossen Metrawatt GmbH. The capacitance measured for this arrangement, e.g. for polystyrene as the dielectric layer, was C=1.15 nF, and on the basis of the electrode geometry a capacitance per unit area of C=10.9 nF/cm² resulted.

### f) Electrical Characterization

The characteristic lines were measured with the aid of two current-voltage sources (Keithley 238). One voltage source applies an electrical potential to the source and drain and thereby determines the current which flows, while the second applies an electrical potential to the gate and source. The source and drain were contacted with printed-on Au pins, and the highly doped Si wafer formed the gate electrode and was contacted via the reverse, scratched free from oxide. The characteristic lines were plotted and evaluated by the known method, as described e.g. in “Organic thin-film transistors: A review of recent advances”, C. D. Dimitrakopoulos, D. J. Mascaro, IBM J. Res. & Dev. vol. 45 no. 1, January 2001.

The electrical characterization (FIG. 1) gave the following relevant parameters for this transistor construction:
i. Mobility
ii. On/Off ratio I_{D}(U_{G}=−60 V)/ I_{D}(U_{G}=0 V) Note: The sensitivity of the Off current measurement I_{D} (U₀=0 V) is limited to approx. 1 nA due to an incompletely shielded cable.
iii. Threshold voltage

The results of the electrical characterization of these OFETs (FIG. 1) are summarized in Table 1.

TABLE 1

| | Dielectric | Mobility | Mobility | |
|---|---|---|---|---|
| | intermediate | (saturation) | (linear) | On/Off- |
| Example | layer | [cm²/Vs] | [cm²/Vs] | ratio |
| 6a¹⁾ | ODMS | 0.614 | 0.519 | 3.0 × 10⁵ |
| 6b¹⁾ | ODMS | 0.221 | 0.0976 | 2.5 × 10⁵ |
| 6c²⁾ | PS | 0.274 | 0.202 | 1.2 × 10⁶ |
| 6d²⁾ | PS | 6.68 × 10⁻⁴ | 5.53 × 10⁻⁴ | 340 |
| 6e³⁾ | ODMS | 0.43 | 0.55 | 1.0 × 10⁶ |
| 6f³⁾ | HMDS | 0.47 | 0.26 | 2.5 × 10⁶ |
| 6g³⁾ | PS | 1.08 | 0.95 | 2.5 × 10⁶ |
| 6h³⁾ | Paraloid B72 | 0.58 | 0.32 | 2.4 × 10⁶ |
| 6i³⁾ | COC 5013 | 2.80 | 1.08 | 4.5 × 10⁶ |
| 6j³⁾ | ODMS | 3.90 | 0.78 | 2.4 × 10⁷ |
| 6k³⁾ | Paraloid B72 | 1.36 | 0.47 | 6.2 × 10⁶ |

¹⁾Purification by column chromatography
²⁾Purification by recrystallization
³⁾Purification by sublimation

Explanation:
Example 6a: OFET with 2-tridecyl-BTBT=compound (I-1) from Preparation Example 1.
Example 6b: OFET with 2-dodecyl-BTBT=compound (I-2) from Preparation Example 2.
Example 6c: OFET with 2-hexyl-BTBT=compound (I-3) from Preparation Example 3.
Example 6d: OFET with 2-ethyl-BTBT=compound (I-4) from Preparation Example 4.
Example 6e-6k: OFET with 2-tridecyl-BTBT=compound (I-1) from Preparation Example 1.

ODMS=octyldimethylchlorosilane

HMDS=hexamethyldisilazane

PS=polystyrene

### Example 7

A silicon wafer with a 100 nm thick silicon oxide layer was first rinsed with acetone and isopropanol and dried. A 30 nm thick aluminium layer was then deposited on the oxide surface as a gate electrode with a vapour deposition rate of 3-4 Å/second. The aluminium layer was oxidized on the surface by an oxygen plasma treatment of 2 min, so that an approx. 4 nm thick AlOₓ layer formed. The substrate produced in this way was immersed in a solution of [12-([1]benzothieno[3,2-b]benzothien-2-yl)-dodecyl]phosphonic acid (compound from Example 4) in tetrahydrofuran (0.3 mmol/l) for 20 hours. The substrate was then rinsed off with tetrahydrofuran and dried. 30 nm gold contacts for the source and drain electrodes were then vapour-deposited via a shadow mask in a Univex vapour deposition unit (vapour deposition rate: 0.1 Å/second for the first 10 nm, then 0.2 Å/second). The electrode geometries were W×L=150×8 nm. In the transistor measurement, a drain current to gate current ratio of two orders of magnitude and a modulation of the drain current and an On/Off ratio in the region of several nanoamperes were measured.

### Example 8

A silicon wafer with a 100 nm thick silicon oxide layer was first rinsed with acetone and isopropanol and dried. A 30 nm thick aluminium layer was then deposited on the oxide surface as a gate electrode with a vapour deposition rate of 3-4 Å/second. The aluminium layer was oxidized on the surface by an oxygen plasma treatment of 2.5 min, so that an approx. 5 nm thick AlOₓ layer formed. An approx. 30 nm thick layer of 2-tridecyl-[1]benzothieno[3,2-b][1]benzothiophene (2-tridecyl-BTBT; compound (I-1) from Preparation Example 1)) was vapour-deposited on to the substrate. 30 nm gold contacts for the source and drain electrodes were then vapour-deposited via a shadow mask in a Univex vapour deposition unit (vapour deposition rate: 0.1 Å/second for the first 10 nm, then 0.2 Å/second). The electrode geometries were W×L=500×200 μm. The transistor measurements gave a charge mobility of 3.2 cm²/Vs (see FIGS. 3 and 4).

### Example 9

A silicon wafer with a 100 nm thick silicon oxide layer was first rinsed with acetone and isopropanol and dried. A 30 nm thick aluminium layer was then deposited on the oxide surface as a gate electrode with a vapour deposition rate of 3-4 Å/second. The aluminium layer was oxidized on the surface by an oxygen plasma treatment of 2.5 min, so that an approx. 5 nm thick AlOₓ layer formed. The substrate produced in this way was immersed in a solution of tetradecanephosphonic acid (C₁₄PA) in tetrahydrofuran (0.3 mmol/l) for 20 hours. The substrate was then rinsed off with tetrahydrofuran and dried. An approx. 30 nm thick layer of 2-tridecyl-[1]benzothieno[3,2-b][1]benzothiophene (2-tridecyl-BTBT; compound (I-1) from Preparation Example 1)) was vapour-deposited on to the substrate treated in this way. 30 nm gold contacts for the source and drain electrodes were then vapour-deposited via a shadow mask in a Univex vapour deposition unit (vapour deposition rate: 0.1 Å/second for the first 10 nm, then 0.2 Å/second). The electrode geometries were W×L=500×200 μm. The transistor measurements gave a charge mobility of 1.9 cm²/Vs (see FIGS. 5 and 6).

1-15. (canceled)

16. A compound of the general formula (I) 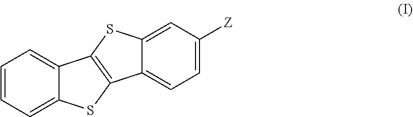
wherein Z corresponds to
a C₁-C₂₂-alkyl radical substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl),
a C₅-C₁₂-cycloalkyl radical substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl),
a C₆-C₁₄-aryl radical or heteroaryl radical from the group of the thienyl, pyrryl, furyl or pyridyl radicals substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²⁻ⁿ (R²═C₁-C₁₈-alkyl, n=an integer from 1 to 3), thiol groups or trialkoxysilyl radicals —Si(OR³)₃ (R³═C₁-C₁₈-alkyl), or
a C₇-C₃₀-aralkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R3═C₁-C₁₈-alkyl) or
a trialkylsilyl radical R⁵R⁶R⁷Si, in which R⁵, R⁶, R⁷ independently of each other are identical or different C₁-C₁₈-alkyl radicals,

17. The compound according to claim 16, wherein Z represents a radical -A-R⁴, in which
A represents an unbranched C₁-C₁₈-alkylene radical and
R⁴ represents halogen, a thiol group or a phosphonic acid or phosphonic acid ester group —P(O)(OR¹)₂ (wherein the radicals R^{I} can be identical or different and correspond to a hydrogen atom or C₁-C₁₂-alkyl),

18. The compound according to claim 17, wherein
A represents an unbranched C₁-C₁₂-alkylene radical and
R⁴ represents a phosphonic acid group —P(O)(OH)₂.

19. A semiconductor layer comprising compound of the general formula (I) 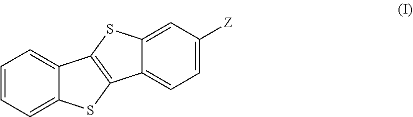
wherein Z corresponds to
a C₁-C₂₂-alkyl radical optionally substituted by halogen, phosphonic acid or phosphonic acid ester groups —P(O)(OR')₂ (wherein the radicals R¹ can be identical or different and correspond to a hydrogen atom or C₁-C₁₂-alkyl), sulphonic acid groups —SO₃H, halosilyl radicals —SiHalₙR²⁻ⁿ (R²═C₁-C₁₈-alkyl, n=an integer from 1 to 3), thiol groups or trialkoxysilyl radicals —Si(OR³)₃ (R³═C₁-C₁₈-alkyl),
a C₅-C₁₂-cycloalkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²⁻ⁿ (R²═C₁-C₁₈-alkyl, n=an integer from 1 to 3), thiol groups or trialkoxysilyl radicals —Si(OR³)₃ (R³═C₁-C₁₈-alkyl),
a C₆-C₁₄-aryl radical or heteroaryl radical from the group of the thienyl, pyrryl, furyl or pyridyl radicals optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═CC₁-C₁₈-alkyl), or
a C₇-C₃₀-aralkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C_{hd 18}-alkyl, n=an integer from 1 to 3), thiol groups or trialkoxysilyl radicals —Si(OR³)₃ (R³═C₁-C₁₈-alkyl) or
a trialkylsilyl radical R⁵R⁶R⁷Si, in which R⁵, R⁶, R⁷ independently of each other are identical or different C₁-C₁₈-alkyl radicals.

20. The semiconductor layer according to claim 19, wherein in the general formula (I) Z represents a radical -A-R⁴, in which
A represents a C₁-C₂₂-alkylene radical and
R⁴ represents a halogen, a phosphonic acid or phosphonic acid ester group —P(O)(OR¹)₂ (wherein the radicals R^{I} can be identical or different and correspond to a hydrogen atom or C₁-C₁₂-alkyl), a sulphonic acid group —SO₃H, a halosilyl radical —SiHalₙR²₃₋ₙ (R²═C₁-C₁₈-alkyl, n=an integer from 1 to 3), a thiol group, a trialkoxysilyl radical -Si(OR³)₃ (R³═C₁-C₁₈-alkyl), a C₆-C₁₄-aryl radical or heteroaryl radical from the group of the thienyl, pyrryl, furyl or pyridyl radicals,
and wherein the semiconductor layer comprises a monomolecular layer of the compounds of this general formula (I).

21. An electronic component comprising the semiconductor layer according to claim 19.

22. The electronic component according to claim 21, wherein the component is a field effect transistor, a light-emitting component, a photovoltaic cell, a laser or a sensor.

23. The electronic component according to claim 21, wherein Z corresponds to a C₁-C₂₂-alkyl radical, a C₅-C₁₂-cycloalkyl radical, a C₆-C₁₄-aryl radical or heteroaryl radical from the group of the thienyl, pyrryl, furyl or pyridyl radicals, a C₇-C₃₀-aralkyl radical or a trialkylsilyl radical R⁵R⁶R⁷Si, in which R⁵, R⁶, R⁷ independently of each other are identical or different C₁-C₁₈-alkyl radicals, and wherein the electronic component is a field effect transistor.

24. A process for the production of an electronic component, comprising the process steps:
i) providing a substrate;
ii) applying to the substrate of a layer comprising compounds of the general formula (I) 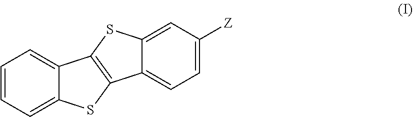
wherein Z corresponds to
a C₁-C₂₂-alkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl),
a C₅-C₁₂-cycloalkyl radical optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl),
a C₆-C₁₄-aryl radical or heteroaryl radical from the group of the thienyl, pyrryl, furyl or pyridyl radicals optionally substituted by halogen, phosphonic acid or phosphonic acid ester groups —P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl), or
a C₇-C₃₀-aralkyl radical optionally substituted by halogen, phosphonic acid or phosphonic acid ester groups −P(O)(OR¹)₂ (wherein the radicals R¹ can be identical or different and correspond to a hydrogen atom or C₁-C₁₂-alkyl), sulphonic acid groups —SO₃H, halosilyl radicals —SiHalₙR²₃₋ₙ (R²═C₁-C₁₈-alkyl, n=an integer from 1 to 3), thiol groups or trialkoxysilyl radicals —Si(OR³)₃ (R³═C₁-C₁₈-alkyl) or
a trialkylsilyl radical R⁵R⁶R⁷Si, in which R⁵, R⁶, R⁷ independently of each other are identical or different C₁-C₁₈-alkyl radicals.

25. The process according to claim 24, wherein the compounds of the general formula (I) are applied to the substrate from solutions or by vapour deposition.

26. The process according to claim 24, wherein in the general formula (I)
Z corresponds to a radical -A-R⁴, in which
A represents a C₁-C₂₂-alkylene radical and
R⁴ represents a halogen, a phosphonic acid or phosphonic acid ester group —P(O)(OR¹)₂ (wherein the radicals R¹ can be identical or different and correspond to a hydrogen atom or C₁-C₁₂-alkyl), a sulphonic acid group —SO₃H, a halosilyl radical —SiHalₙR²₃₋ₙ (R^{2═=C}₁-C₁₈-alkyl, n=an integer from 1 to 3), a thiol group, a trialkoxysilyl radical —Si(OR³)₃ (R³═C₁-C₁₈-alkyl) or a C₆-C₁₄-aryl radical or heteroaryl radical from the group of the thienyl, pyrryl, furyl or pyridyl radicals, and wherein the compounds of this general formula (I) are applied to the substrate as a monomolecular layer.

27. An electronic component obtainable by the process according to claim 24.

28. The semiconductor layer as claimed in claim 19, wherein Z corresponds to a radical -A-R⁴, in which
A represents a C₁-C₂₂-alkylene radical and
R⁴ represents a halogen, a phosphonic acid or phosphonic acid ester group —P(O)(OR¹)₂ (wherein the radicals R¹ can be identical or different and correspond to a hydrogen atom or C₁-C₁₂-alkyl), a sulphonic acid group —SO₃H, a halosilyl radical —SiHalₙR²₃₋ₙ (R²═C₁-C₁₈-alkyl, n=an integer from 1 to 3), a thiol group, a trialkoxysilyl radical —Si(OR³)₃ (R³═C₁-C₁₈-alkyl) or a C₆-C₁₄-aryl radical or heteroaryl radical from the group of the thienyl, pyrryl, furyl or pyridyl radicals, and wherein the semiconductor layer comprises a monomolecular layer of the compounds of this general formula (I).

29. A dielectric layer which comprises the semiconductor layer according to claim 19.
